(19) United States
(12) Patent Application Publication
(10) Pub. No.: US 2016/0150652 A1
(43) Pub. Date: May 26, 2016

(54) CIRCUIT SHEET ARRANGEMENT

(71) Applicant: NOVALIA LTD, Cambridge (GB)

(72) Inventor: Kate Stone, Cambridge (GB)

(21) Appl. No.: 14/905,241

(22) PCT Filed: Jul. 15, 2014
(86) PCT No.: PCT/GB2014/052161

§ 371 Date: Jan. 14, 2016

(30) Foreign Application Priority Data
Jul. 15, 2013 (GB) 1312607.3

(51) Int. Cl. H05K 1/18; H05K 1/02

(52) U.S. Cl. CPC H05K 1/189; H05K 1/0213; H05K 2201/09218

(57) ABSTRACT

An article comprises an electronic component, such as an integrated circuit or packaged integrated circuit, and a circuit sheet arrangement. The circuit sheet arrangement may comprise a flexible planar substrate and conductive tracks formed on a face of the substrate. The substrate is configured to have an aperture enclosed by surrounding portion of the substrate and to have at least two arms supporting respective conductive tracks which extend into the aperture from the surrounding portions. The electronic component is disposed over the aperture and is attached to conductive tracks on the arms, for example, using conductive glue or ink.

The present invention relates to a circuit sheet arrangement.

### BACKGROUND

Electronic components are increasingly being incorporated into printed articles, such as books, posters and greeting cards, to allow printed articles to become more interactive. Examples of interactive printed articles are described in GB 2 464 537 A, WO 2004 077286 A, WO 2007 035115 A and DE 993 4312672 A.

GB 2 482 039 A describes a device (such as a printed article, a book, a game or a greeting card) which comprises a laminate of at least two layers. Components, such as a light emitting diode, an integrated circuit, a battery etc, are provided between two layers and at least one of the layers supports a conductive track connecting the components.

GB 2 472 047 A describes a device in the form of a packaged component, such as a light emitting diode or an integrated circuit, which is formed over a slot cut in a substrate.

The devices described in GB 2 482 039 A and GB 2 472 047 A can be formed from plastic or fibre-based material such as paper or card. Accordingly, the devices tend to be flexible. However, the components tend to be inflexible and so if the devices are bent or twisted, then connections between a component and a supporting substrate may be broken.

The present invention seeks to avoid or ameliorate this problem.

### SUMMARY

According to a first aspect of the present invention there is provided a circuit sheet arrangement comprising a flexible planar substrate and conductive tracks formed on a face of the substrate. The substrate is configured to have an aperture enclosed by surrounding portion of the substrate and to have at least two arms supporting respective conductive tracks which extend into the aperture from the surrounding portions.

According to a second aspect of the present invention there is provided a circuit sheet arrangement comprising at least two co-planar flexible planar substrates and conductive tracks formed on respective faces of the substrates. The substrates are arranged around an aperture and each substrate is configured to have at least one arm supporting respective conductive track(s) which extend into the aperture.

Thus, a stiff electronic component, such as a light emitting diode or integrated circuit, can be mounted onto the circuit sheet arrangement formed from flexible material and the arrangement can withstand flexion and/or torsion.

The flexible planar substrate may be substantially non-stretchable.

Each arm may comprise at least one turn. For example, each arm may comprise one, right-angle turn. At least some of the arms may be arranged in opposite pairs. Distal ends of each pair of arms may point in opposite directions.

The arms may be connected to a central node, such as platform. The arms and central node may be unitary, i.e. formed in the same layer of material. This central node may help the arms to maintain or to return to a stable position when not stretched or twisted.

Each arm may include one or more slits arranged to allow ends of the arms to be moved apart in the same plane. This allows the arms not only twist and bend, but also stretch or stretch further. The arm may comprise first and second opposite edges and wherein at least one slit extends from each opposite edge. The arm may have a line running midway between the opposite edges and wherein at least one slit crosses the midway line. The arm may comprise at least one slit which extends between but does not reach the opposite edges. A pair of adjacent slits (for example, along a straight section of an arm) may be parallel.

The substrate may comprise a fibre-based material such as paper, card, or cardboard and/or plastic. The substrate may comprise a laminate.

According to a third aspect of the present invention there is provided an article comprising an electronic component and a circuit sheet arrangement. The electronic component may be disposed over the aperture and is attached to conductive tracks on the arms.

The electronic component may be bonded to the tracks by conductive glue, conductive ink and/or conductive tape.

The article may be a printed article having indicia (words and/or images) formed of ink or paint printed thereon.

The article may be a game. The article may be a greetings card.

### BRIEF DESCRIPTION OF THE DRAWINGS

Certain embodiments of the present invention will now be described, by way of example, with reference to the accompanying drawings, in which:

FIG. 1 is a plan view of an article which includes a circuit sheet arrangement and an electronic component mounted onto the circuit sheet arrangement;

FIG. 1a shows an arm portion of the circuit sheet arrangement shown in FIG. 1 in more detail;

FIG. 1a is a cross-sectional view an article taken along the line A-A′;

FIG. 2 illustrates bending of the article;

FIG. 3 illustrates twisting of the article;

FIG. 4 illustrates a two-arm, two-piece circuit sheet arrangement;

FIG. 5 illustrates a two-arm, single-piece circuit sheet arrangement;

FIG. 6 illustrates a four-arm, single-piece circuit sheet arrangement;

FIG. 7 illustrates a four-arm, single-piece circuit sheet arrangement which includes a platform; and

FIG. 8 illustrates a first slotting arrangement of an arm;

FIG. 9 illustrates a second slotting arrangement of an arm; and

FIG. 10 illustrates a more complex circuit sheet arrangement.

### DETAILED DESCRIPTION OF CERTAIN EMBODIMENTS

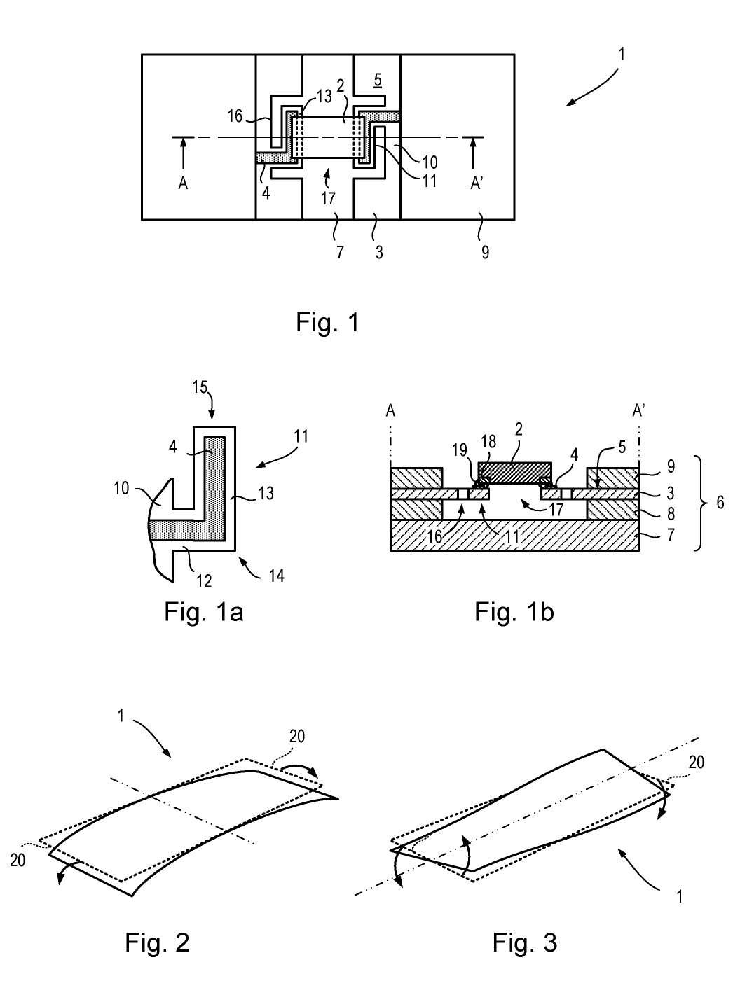

Referring to FIGS. 1, 1a and 1b, an article 1 is shown which includes an electronic component 2 supported on a two-part circuit sheet 3 having conductive tracks 4 disposed on an upper surface 5. The conductive tracks 4 comprise conductive ink formed by a printing process, such as gravure, offset, flexography, screen or inkjet. However, the conductive tracks 4 may be formed from foil formed by stamping.

The circuit sheet 3 forms part of a laminate 6 which includes a base sheet 7, an intermediate sheet 8 and a top sheet 9. The sheets 9 comprise card and are bonded together by glue (not shown).

As shown in FIG. 1a, each part of the circuit sheet 3 comprises a main portion 10 and an arm 11 extending from main portion 10. Each arm 11 is generally ‘L’-shaped having first and second sections 12, 13. The first portion 12 is proximal to the main sheet portion 10 and the second portion 13 is distal to the main sheet portion 10.

The first and second sections 12, 13 are straight sections. The second portion 13 extends between an elbow 14 and a free end 15 of the arm 11. The arm 11 is formed by slots 16 running between the main sheet portion 10 and arm 11. A conductive track 4 runs along each arm 13. As will be explained in more detail later, more than one conductive track 4 can run along each arm 11.

As shown in the FIG. 1, the second sections 13 are arranged opposite each other, are parallel and point in opposite directions.

A gap (or “aperture”) 17 is formed between the two main sheet portions 10 of the circuit sheet parts 3. The arms 11 extend into the gap 17.

The electronic component 2 is mounted onto the arms lo so that it bridges the gap 17. The electrical terminals 18 under the underside of the component 2 are bonded to the tracks 4 using conductive glue 19. However, a conductive tape can be used.

Referring also to FIGS. 2 and 3, opposite ends 20 (or sides) of the article 1 can be bent and/or twisted. However, flexional or torsional movement is at least partially decoupled from the electronic component 2 by virtue of the arms 11. Thus, stress on the connection between the glue 19 can be reduced.

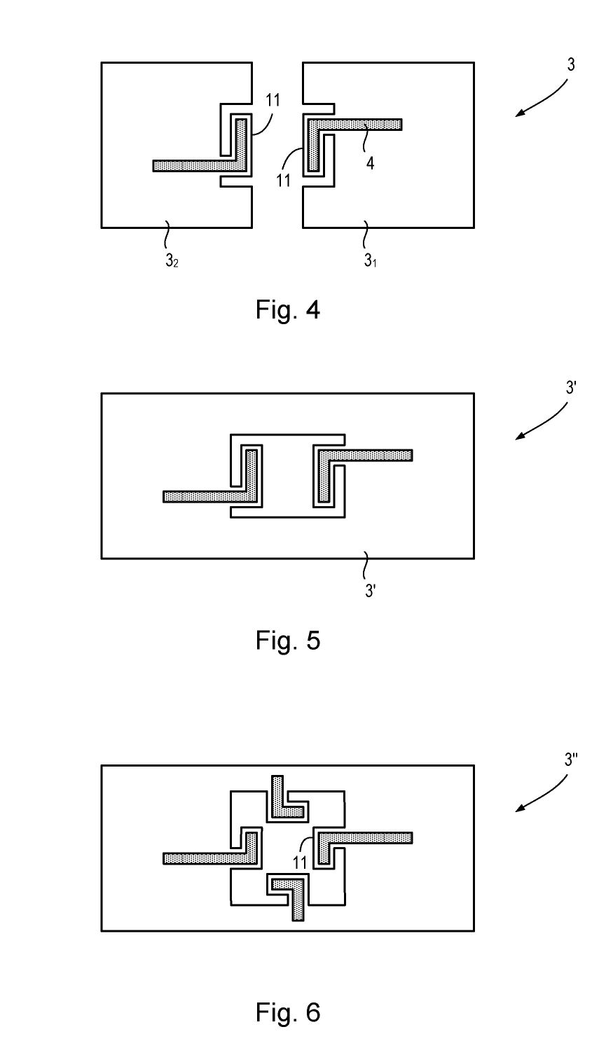

Referring to FIG. 4, the circuit sheet 3 used in the article 1 shown in FIG. 1 comprises two separate parts 3₁, 3₂, i.e. two sheets, and has two arms 11. The sheets 3₁, 3₂ are coplanar. This arrangement is used to form an “open” aperture, i.e. an aperture which is not necessarily surrounded by the same sheet.

Referring to FIG. 5, a circuit sheet 3′ may comprise a single sheet. This arrangement is used to form an “closed” aperture, i.e. an aperture which is surrounded by the same sheet.

Referring to FIG. 6, a circuit sheet arrangement 3″ may have more than two arms, for example, four arms 11. The arms 11 may be arranged in pairs. For each pair, the arms are arranged are parallel and point in opposite directions. The arms may be opposite each other or may be offset (to the side).

The arms 11 need not be all the same size and/or the same configuration.

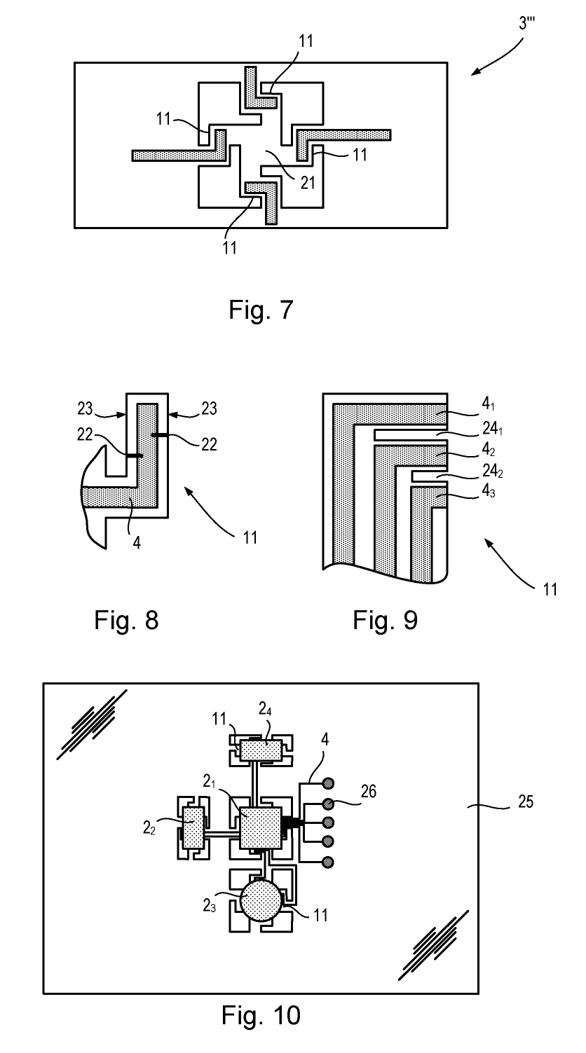

Referring to FIG. 7, the circuit sheet arrangement 3′″ may include a central node 21 which connects the arms 11.

Referring to FIG. 8, an arm 11 may include slots 22 along extending into the body of the arm 11 from an edge 23. The arms slots 22 can be arranged in pairs along a section of the arm, extending inwardly from opposite edged and spaced along the arm. This can help the arm 11 to extend. In FIG. 8, only two slots 22 are shown. However, there may be three, four or more slots 22. In FIG. 8, the slots 22 also cut into the conductive track 4. However, the conductive track 4 may be configured to run between the edges 23 and between the tracks 4, i.e. to meander along the arm 11.

Referring to FIG. 9, an arm 11 may include more than one track 4₁, 4₂, 4₃, for example, running in parallel. At the end of the arm, the tracks 4₁, 4₂, 4₃ may be separated by slots 24₁, 24₂. This can help to decouple movement of between the tracks and, thus, help to reduce stress of any glue (not shown) attached to the track 4₁, 4₂, 4₃ at the end of the arm 11.

Referring to FIG. 10, a more complex circuit sheet arrangement 25 is shown. The circuit sheet includes four sets of arms 11 which are used to support four components on the same sheet 25. The sheet may be formed from a fibre-based material such as paper or card. The components can include a microcontroller 2₁, a battery 2₂, a buzzer 2₃ and an LED 2₄. A set of conductive pads 26, for example formed from conductive ink or foil, are provided on the sheet 25 to provide capacitive touch user input.

The more complex circuit sheet arrangement 25 may be used in an article, such as game or card. The article may be a printed article supporting printed indicia. The article may comprise laminate, for example, as described in GB 2 472 047 A. Different layers in the laminate may provide different arms. Thus, a component may be suspended in a cavity formed by several layers and may be connected to conductive tracks in different layers by arms extending from different main portions of different layers.

The articles herein described may be formed using printing and converting processes, for example, as described in GB 2 482 039 A and GB 2 472 047 A.

An article which incorporates an electronic device and in which part(s) of a circuit forming the electric device is formed on a fibre-based material can help to reduce the amount of plastic used and, thus, be more environmentally friendly.

It will be appreciated that many modifications may be made to the embodiments hereinbefore described. Such modifications may involve equivalent and other features which are already known in the design, manufacture and use of articles formed from fibre-based sheets, which are printed articles and which include conductive tracks formed from ink or foil, parts thereof and which may be used instead of or in addition to features already described herein. Features of one embodiment may be replaced or supplemented by features of another embodiment.

Card need not be used, but other fibre-based materials, such as paper can be used. Inflexible plastic or even glass can be used. Laminates of, for example card and plastic, can be used.

Although conductive ink can be used, one or more of the conductive regions, such as pads, terminals, tracks etc., can be formed from foil comprising for example, aluminium, copper, gold or aluminium, formed for example, by hot- or cold-foil stamping.

The article may be or may be used in not only in games, but also books, calendars, greeting cards, product packaging or point of sale displays.

The arms need not have straight sides or sections. The sides or sections can be curved. The arms need not have an elbow, but can be slotted. The arms can include more than one elbow.

More than one circuit sheet may be used. For example, two or sets of circuit sheet may be used to form “open” apertures and one of the circuit sheet or a different circuit sheet can be used to form one or more “closed” apertures.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A circuit sheet arrangement comprising:
a flexible planar substrate; and
conductive tracks formed on a face of the substrate;
wherein the substrate is configured to have an aperture enclosed by surrounding portion of the substrate and to have at least two arms supporting respective conductive tracks which extend into the aperture from the surrounding portions.

2. A circuit sheet arrangement comprising:
at least two co-planar, flexible planar substrates; and
conductive tracks formed on respective faces of the substrates;
wherein the substrates are arranged around an aperture and wherein each substrate is configured to have at least one arm supporting respective conductive track(s) which extend into the aperture.

3. A circuit sheet arrangement according to claim 1, wherein the flexible planar substrate(s) is (are) substantially non-stretchable.

4. A circuit sheet arrangement according to claim 1, wherein each arm comprising at least one turn.

5. A circuit sheet arrangement according to claim 4, wherein each arm comprising one, right-angle turn.

6. A circuit sheet arrangement according to claim 1, wherein at least some of the arms are arranged in opposite pairs.

7. A circuit sheet arrangement according to claim 6, wherein distal ends of each pair of arms point in opposite directions.

8. A circuit sheet arrangement according to claim 1, wherein the arms are connected to a central node.

9. A circuit sheet arrangement according to claim 1, wherein each arm includes one or more slits arranged to allow ends of the arms to be moved apart in the same plane.

10. A circuit sheet arrangement according to claim 1, wherein the arm comprises first and second opposite edges and wherein at least one slit extends from each opposite edge.

11. A circuit sheet arrangement according to claim 9, the arm has a line running midway between the opposite edges and wherein at least one slit crosses the midway line.

12. A circuit sheet arrangement according to claim 9, wherein the arm comprises at least one slit which extends between but does not reach the opposite edges.

13. A circuit sheet arrangement according to claim 9, wherein a pair of adjacent slits are parallel.

14. A circuit sheet arrangement according to claim 1, wherein the substrate comprises paper.

15. A circuit sheet arrangement according to claim 1, wherein the substrate comprises card.

16. A circuit sheet arrangement according to claim 1, wherein the substrate comprises plastic.

17. A circuit sheet arrangement according to claim 1, wherein the substrate comprises a laminate.

18. An article comprising:
an electronic component; and
a circuit sheet arrangement according to claim 1;
wherein the electronic component is disposed over the aperture and is attached to conductive tracks on the arms.

19. An article according to claim 18, wherein the article is a game.

20. An article according to claim 18, wherein the article is a greetings card.
